(19) United States
(12) Patent Application Publication
(10) Pub. No.: US 2006/0045727 A1
(43) Pub. Date: Mar. 2, 2006

(54) Apparatus for order picking goods in a goods warehouse

(76) Inventor: Volker Jungbluth, Seligenstadt (DE)

Correspondence Address: VAN DYKE, GARDNER, LINN AND BURKHART, LLP, 2851 CHARLEVOIX DRIVE, S.E., P.O. BOX 888695, GRAND RAPIDS, MI, 49588-8695, US

(21) Appl. No.: 11/183,688

(22) Filed: Jul. 18, 2005

(30) Foreign Application Priority Data
Jul. 23, 2004 (DE) 10 2004 035 820.6

(51) Int. Cl. H01L 21/677

(52) U.S. Cl. 414/800

(57) ABSTRACT

An apparatus for order picking goods in a goods warehouse, in particular a high-bay warehouse, with the aid of an industrial conveying means which can be moved along a row of racks and on which goods connected with an order can be assembled in load units by an order picker travelling with it. In order to configure an apparatus for order picking goods in a warehouse in such a way that very high commissioning performances can be achieved, the industrial conveying means may be constructed as an order picking platform (6), on which there is installed an order picking workstation (7) which has physical interfaces with the rear row of racks (5) and a load unit interchange between the order picking workstation (7) and the rack (5) and/or a loading unit which can be moved rearward along the row of racks.

### BACKGROUND OF THE INVENTION

The invention relates to an apparatus for order picking goods in a goods warehouse and, in particular, to a high-bay warehouse, with the aid of an industrial conveying means which can be moved along a row of racks and on which goods connected with an order can be assembled in load units by an order picker travelling with the conveying means.

Increasing requirements with regard to the performance at order picking workstations come up against the limits of the order picking technology currently used. The workstations, which are normally constructed manually, are located in the environment of a highly technical plant. Nevertheless, according to the existing conditions, the performance limits are normally not determined by the operator but by the system configuration and conveying technology. In addition to the requirements with respect to the increase in performance, there are further requirements, for example, to provide the articles in a defined sequence, which means that the complexity of plants increases further as a result of the buffering and pre-sorting and, normally, gives rise to costs in terms of performance.

In order picking technology, according to the current state of the art, two principles are predominantly applied. Firstly, the principal of “man to goods”, in which the order picker is guided to the appropriate stored goods. This can be done, for example, by means of storage and retrieval appliances in high-bay warehouses, by means of order picking stackers along the rack systems in or on foot along order picking sections.

Secondly, the principal of “goods to man” exists, in which the stored goods are conveyed by conveying devices to a stationary workstation at which goods are removed from the storage units and the storage units are generally stored back.

As a result of the increasing requirements with respect to the picking performance of an individual order picker, performance limits result in accordance with the above-described principle of “man to goods”, which are limited by the warehouse dimensions and the dynamic properties of the industrial truck and also the performance of the order picker. By means of technical aids, such as “pick by light” displays, the navigation of the operator can be accelerated. However, optical displays are needed on each order picking compartment, which entails a high level of investment, depending on the number of articles and the order picking aisle length.

For the “goods to man” principle, powerful conveying means are needed, since the load units must be provided at a stationary place. As a result of the restricted conditions at a stationary workstation, which have to be maintained for ergonomic and performance reasons, usually insufficient area remains to effect disentanglement of the conveying streams leading in and out. As a result, high throughputs of individual streams are caused, which reach the physical limits or lead to costly investment. Here, it is possible for the goods to back up and for the material flow to be disrupted. This inevitably leads to a stoppage of the working operations and thus to costs in terms of performance of the overall system.

### SUMMARY OF THE INVENTION

The present invention provides an apparatus for order picking goods in a warehouse in such a way that very high order picking performances can be achieved in a system which does not have the disadvantages described above.

According to an aspect of the invention, an industrial conveying means constructed as an order picking platform is provided and, on the order picking platform, is installed an order picking workstation which has physical interfaces with the rear row of racks and a load unit interchange between the order picking workstation and the rack and/or a loading unit which can be moved rearward along the row of racks.

This aspect of the invention is thus based on a combination of the principles of “man to goods” and “goods to man”, in that the workstation of the order picker is installed on the movable order picking platform, which moves along a row of racks and which is supplied rearward via a loading unit.

According to another aspect of the invention, the loading unit may be moved rearward along the row of racks, is automated and is constructed as a storage and retrieval appliance or lifting beam system.

It is possible to configure the order picking platform both to be rail-bound and also freely movable. In the latter case, greater flexibility in the use of the order picking platform is possible, for example, if, by means of transposition, an order picking platform is assigned to various rack aisles.

According to another aspect of the invention, the order picking workstation of the order picking platform is subdivided into a gripping zone and a buffer zone. In the gripping zone, the manual order picking operations are carried out. The buffer zone, on the other hand, is used as a variable-use station between the order picking platform and the rack or a holding station for a subsequent change into the gripping zone or into the rack store.

According to another aspect of the invention, the order picking platform has a plurality of conveying levels, of which at least one has the physical interface to the rear row of racks. The number of stopping spaces for the storage units and the number of conveying levels may be configured variably along with the possibility for configuring the material flows on the conveying technology of the level and the number of interfaces to the rack system, which may be defined in accordance with the performance of the order picking workstation.

According to another aspect of the invention, at least one level is preferably provided for picking up the storage units from the rack, at least one level is provided to accommodate the container in which the goods to be picked for an order are stored, separated for the order and, if appropriate, at least one level is provided for sorting and buffering the goods to be picked for an order. In this case, the tasks of the various levels can be interchanged and/or mixed.

In order to increase the capacity of the order picking workstation and to simplify the conveying sequences for the order picker, at least the level provided for sorting and buffering the goods to be picked for an order may be connected to one or more of the other levels via a vertical transposer which is arranged on the order picking platform. Thus, the storage units which are not required in the gripping region at that instant can be displaced temporarily to another level, from where they can be retrieved as required or from where they can be disposed of.

To this end, one or more of the levels may be provided with a horizontal conveyor system for the transport of the storage units. It is possible to use known conveying systems, whose selection depends on the respective requirements and conditions.

In order to increase the performance of the automatic storage system, the order picking platform may be moved along a plurality of autonomous rack aisles, for example between two rows of racks opposite each other, and the order picking workstation can be loaded and emptied from both racks. The result is a multiplication of the supply and disposal performance.

The order picking workstation on the order picking platform may be provided for single-stage or multi-stage order picking. In the case of single-stage order picking, a job container is brought into the gripping zone of the order picking workstation and all the article containers needed are supplied one after another to the gripping zone. The order picking is carried out successively from the article containers until the job container has been filled. Should a plurality of job containers be needed in order to fulfill an order, then empty containers (reserve containers) are transported into the gripping zone.

In the case of multi-stage order picking, an article container whose articles flow into a plurality of jobs can be placed in the gripping zone. Here, this article can be deposited in the correct quantity in the job containers supplied successively to the gripping zones. If the articles have been allocated by the order picker to all the jobs, then a new article container is introduced into the gripping zones and the necessary job containers are supplied successively to the gripping zones. When a job container has been populated completely or its maximum filling level has been reached, this is stored back in the rack or removed from store on a continuous conveyor and supplied to the appropriate next process step. Empty article containers that have been picked for an order can remain on the vehicle and be used as new job containers or stored back in the rack system.

According to an aspect of the invention, the workstation can have supporting elements which accelerate the manual order picking task. For example, the order picking workstation can be provided with electronically controlled display elements in order to assist the picking of an order, for example, with the known “pick by light” technology.

The destination control of the movable order picking platform may be carried out automatically, according to an aspect of the invention. After an interchange of the load units between the platform and rack has been carried out, the platform moves automatically to the next transfer station of the rack. During this travel time, the order picking process can be continued on the platform.

In addition, the provision and disposal of the load units at the appropriate transfer stations in the rack can be coordinated by a higher-order computer unit. In this case, appropriate algorithms lead to the provision being carried out in a forward-looking manner in order to minimize the load cycles and to optimize the provision sequence and thus the travel times.

The order picking data and provisioning information and, if appropriate, the intended direction of travel of the order picking platform, according to an aspect of the invention, are transmitted to the operator on a display which travels with him, or are led to the order picking display. If the order picker knows the direction of travel, he is able to adapt better to the acceleration and braking conditions of the order picking platform.

The configuration of the order picking workstation may be carried out from ergonomic points of view. Here, the acceleration ramps of the order picking platform are set such that the order picker does not experience any impairment. The order picker is protected in the direction of travel against the consequences of excess acceleration (emergency stop) by suitable protective measures.

Aspects of the invention have a series of advantages as compared with the known solutions. Because of the possible chronological superimposition of the order picking process, travel and load unit interchange, important operations may be carried out in parallel and can thus contribute to an increase in the order picking performance. Because the supply and disposal of the order picking platform can be carried out via a conventional automatic storage system, costly, complicated preliminary storage zones can be dispensed with. The performance of the storage system may be distributed over an order picking area along the row of racks, where the necessary containers can be provided along the adjacent row of racks in at least two or three levels. As a result, disentanglement of the material flow is brought about; this is because the conveying stream is not just restricted to a few stations as in the case of a stationary workstation. Thus, the complexity and operational capacity of the surrounding conveying engineering are also reduced.

A further increase in the performance of the automatic storage system, with a multiplication of the supply and disposal performance, results if the order picking platform is moved along a plurality of autonomous rack aisles. It is also possible for a plurality of order picking platforms to be arranged one above another in front of a row of racks.

As a result of the installation of a buffer level on the platform, the frequency of load unit interchange between rack system and platform is reduced. If the corresponding load unit is needed in the gripping zone again in the near future, then it remains on the platform and is stored in the buffer level. As a result, the frequency of container interchange between the two systems can be reduced and an increase in the performance of the overall system can be made.

The buffer level, which travels concomitantly, can also be used for sequence formation, in that the containers are picked up from the rack system and firstly are moved on the conveying system into another sequence before they change into the gripping zone. The possibility of sequencing on the platform thus does not have a detrimental effect on the performance of the automatic rack system and contributes to the increase in the overall performance.

In terms of conveying engineering, the buffer level can be configured in such a way that sorting is carried out within the level. Because of the limited order picking stations in the gripping zone, it is not necessary to configure an entire row of racks with optical supporting elements. As a result of the restriction to a few order picking stations, potential savings can be created.

These and other objects, advantages and features of this invention will become apparent upon review of the following specification in conjunction with the drawings.

### BRIEF DESCRIPTION OF THE DRAWINGS

FIG. 1 shows a system illustration of the invention with rack connection on one side;

FIG. 2 shows a side elevation of the system according to FIG. 1;

FIG. 3 shows an enlarged illustration of the order picking platform from FIG. 1 in top plan view; and

FIG. 4 shows an arrangement and illustration of the material flows on the order picking platform, according to the invention.

### DESCRIPTION OF THE PREFERRED EMBODIMENT

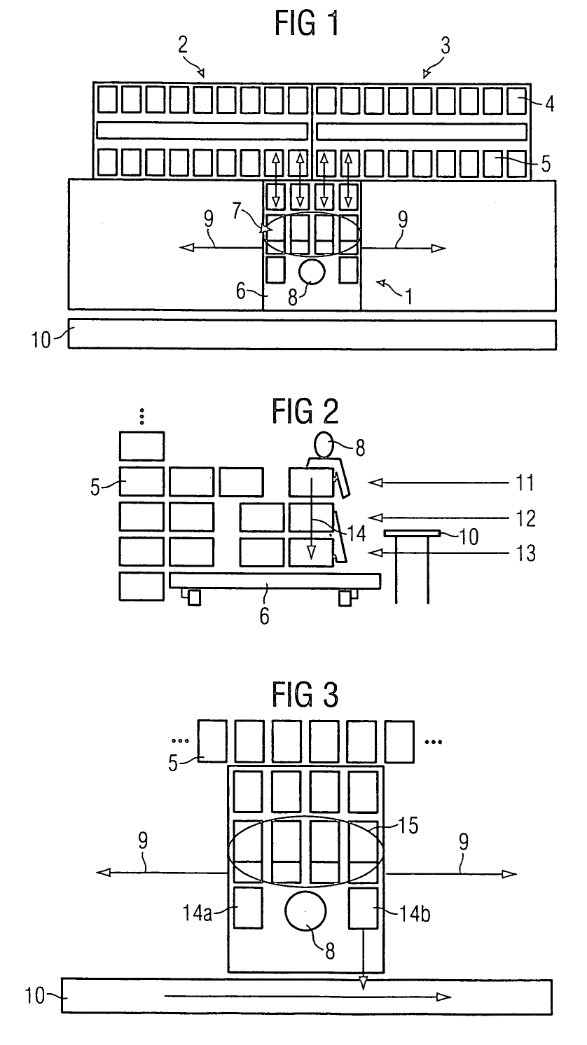

Referring now to the drawings and the illustrative embodiment depicted therein, an order picking apparatus 1, according to the invention, incorporated in a storage system, is illustrated in FIG. 1. It is possible to see two stores 2 and 3 which are served by a single order picking apparatus and which each comprise two rows of racks 4 and 5, of which the row of racks 5 is served by the order picking apparatus 1. The order picking apparatus 1 includes an order picking platform 6, on which the order picking workstation 7 for the order picker 8 is arranged. The order picking platform can be moved with respect to the order picking area in the direction of the arrow 9. In the illustrative embodiment, the platform 6 is guided on rails. On the side of the order picking area opposite the row of racks 5, a continuous conveyor 10 is illustrated, which disposes of the jobs for which orders have been picked. On the order picking platform 6, various storage units are illustrated as rectangular boxes, which are deposited there in various conveying levels of the order picking workstation.

This total of three levels can be seen better in FIG. 2. There, level 1 is designated 11; on it, a plurality of storage units are deposited in a gripping zone, from which the order picker 8 is able to grip the articles to be picked for an order and to deposit them in boxes, which are arranged in the level 12 arranged underneath. The number of storage units made available in the upper gripping level 11 depends on the dimensions of the order picking platform and on the gripping range of the order picker.

Underneath the second level 12 and immediately on the order picking platform, a third level 13 is provided, which can be used for buffering and sorting the storage units. This storage level 13 is connected to the storage levels 11 and 12 located above by a vertical lifting unit 14. In addition, the individual levels 11, 12 and 13 are equipped with conveying systems, which make it easier to shift the storage units and connecting containers in the conveying levels. The conveying system can be configured as desired. At least one of the levels is linked directly to the row of racks 5 and permits the storage units to be stored and removed from store and also supplied and disposed of.

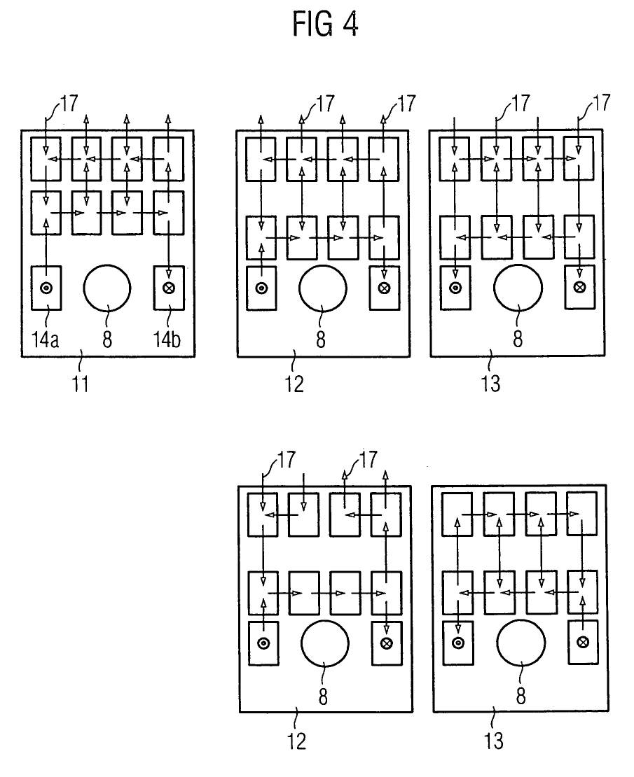

In FIG. 3, the gripping zone of the order picking platform is illustrated at 15. All the storage units located in the gripping range of the order picker 8 are made available there, storage units 16 in the rear row of the order picking platform are transported into the gripping zone, and therefore into the gripping range of the order picker, via the conveying means which are present (not illustrated), in accordance with a defined principle (FIG. 4) and are guided back after the order picking operation. The storage units that are no longer needed are disposed of into the row of racks 5 or, if they are needed for imminent subsequent order picking tasks, are moved into the buffer zone. This is provided in the lowest level 13, as illustrated in FIG. 2, and can be reached with the vertical elevators 14. In this buffer zone, order picking jobs which have been assembled in the second level 12 but have not yet been completed can also be stored temporarily.

In level 13, order picking containers-can also be stored temporarily in order to transfer them later to the continuous conveyor 10 as a sequence. The fact that the levels 11 and 12 are connected to level 13 via the vertical conveyor 14 means that any desired order picking, buffer and sorting operations can be carried out on the order picking platform, according to the invention, while the mobile appliance moves along the row of racks and picks up and disposes of storage units.

In FIG. 4, the material flow in the individual levels 11, 12 and 13 of the order picking platform 6 and in the order picking workstation 7 is illustrated in a schematic representation. The levels 11, 12 and 13 lying one above another are illustrated as beside one another for improved clarity. At the top left in the illustration, the topmost level 11 is illustrated. The arrows reveal where a storage unit at 17 can be transported out of the storage row 5 with the aid of the conveyor system provided in level 11. As can be seen, two vertical lifting devices 14a and 14b are provided; the lifting device 14b is set up to bring a storage unit into one of the levels 12 and 13 located underneath, while the lifting device 14a, as an elevator, transports storage units from level 13 into one of the levels 12 or 11 arranged above. On the right of level 11, levels 12 and 13 are illustrated in FIG. 4. It is possible to see the levels 12 and 13 set up to perform a direct interchange of storage units with the rack 5, it being possible for storage units to be disposed of from level 12, while the rack 5 supplies level 13 with storage units. In the illustration in the lower half of FIG. 4, another variant of the material flow is shown. Here, the interchange with the rack 5 is not possible in all the levels; instead, level 12 is set up to perform the interchange of storage units in two directions with, in each case, two storage spaces in the rack 5, as can be seen from the directions of the arrows. Level 11 behaves in the same way as in the upper half of the figure.

Changes and modifications in the specifically described embodiments can be carried out without departing from the principles of the invention which is intended to be limited only by the scope of the appended claims, as interpreted according to the principles of patent law including the doctrine of equivalents.

The embodiments of the invention in which an exclusive property or privilege is claimed are defined as follows:

1. An order picking apparatus for order picking goods in a goods warehouse, comprising:
an industrial conveying device and an order picking platform travelling with said conveying device, wherein said conveying device is adapted to move along a row of racks and wherein goods connected with an order can be assembled in load units by an order picker at said platform;
an order picking workstation at said order picking platform, wherein said order picking workstation includes a physical interface with said row of racks; and
wherein a load unit can interchange between said order picking workstation and at least one chosen from said row of racks and a loading unit, wherein said loading unit can be moved rearward along said row of racks.

2. The order picking apparatus as claimed in claim 1, wherein said loading unit which can be moved rearward along the row of racks is automated and is defined by at least one chosen from a storage and retrieval appliance and a lifting beam system.

3. The order picking apparatus as claimed in claim 2, wherein said order picking platform is adapted to move on a rail or can be freely moveable.

4. The order picking apparatus as claimed in claim 3, wherein said order picking workstation of said order picking platform is subdivided into a gripping zone and a buffer zone.

5. The order picking apparatus as claimed in claim 4, wherein said order picking platform defines a plurality of conveying levels and at least one conveying level includes a physical interface to the row of racks.

6. The order picking apparatus as claimed in claim 5, wherein at least one conveying level is provided for picking up the storage units from the rack, at least one conveying level is provided to accommodate the container storing the goods to be picked for an order.

7. The order picking apparatus as claimed in claim 6, wherein functions performed by the various levels are adapted to be interchanged or mixed.

8. The order picking apparatus as claimed in claim 7, wherein at least one conveying level sorts and buffers the goods to be picked for an order and is connected to one or more of the other conveying levels via a vertical transporter, said vertical transporter being arranged on said order picking platform.

9. The order picking apparatus as claimed in claim 8, wherein at least one of the levels is provided with a horizontal conveyor system for the transport of storage units.

10. The order picking apparatus as claimed in claim 9, wherein said order picking platform is adapted to be moved between two rows of racks that are opposite each other, and said order picking workstation can be loaded and emptied from both of said two rows of racks.

11. The order picking apparatus as claimed in claim 10, wherein said order picking workstation on said order picking platform is adapted for single-stage or multi-stage order picking.

12. The order picking apparatus as claimed in claim 11, wherein said order picking workstation is provided with electronically controlled display elements to assist order picking.

13. The order picking apparatus as claimed in claim 12, including an automated destination control of said movable order picking platform, wherein said order picking platform is adapted to be navigated to a next transfer station after an interchange of load units with said rack.

14. The order picking apparatus as claimed in claim 13, wherein provision and disposal of load units at an appropriate transfer station in said rack is coordinated by a higher-order computer unit.

15. The order picking apparatus as claimed in claim 14, wherein at least one chosen from order picking data, provisioning information and intended direction of travel of said order picking platform is displayed on said order picking workstation.

16. The order picking apparatus as claimed in claim 1, wherein said order picking workstation is configured ergonomically.

17. The order picking apparatus as claimed in claim 1, wherein said order picking platform is adapted to move on a rail or can be freely moveable.

18. The order picking apparatus as claimed in claim 1, wherein said order picking workstation of said order picking platform is subdivided into a gripping zone and a buffer zone.

19. The order picking apparatus as claimed in claim 1, wherein said order picking platform defines a plurality of conveying levels and at least one conveying level includes a physical interface to the row of racks.

20. The order picking apparatus as claimed in claim 19, wherein at least one conveying level is provided for picking up the storage units from the rack, at least one conveying level is provided to accommodate the container storing the goods to be picked for an order.

21. The order picking apparatus as claimed in claim 19, wherein functions performed by the various levels are adapted to be interchanged or mixed.

22. The order picking apparatus as claimed in claim 1, wherein at least one conveying level sorts and buffers the goods to be picked for an order and is connected to one or more of the other conveying levels via a vertical transporter, said vertical transporter being arranged on said order picking platform.

23. The order picking apparatus as claimed in claim 19, wherein at least one of the levels is provided with a horizontal conveyor system for the transport of storage units.

24. The order picking apparatus as claimed in claim 1, wherein said order picking platform is adapted to be moved between two rows of racks that are opposite each other, and said order picking workstation can be loaded and emptied from both of said two rows of racks.

25. The order picking apparatus as claimed in claim 1, wherein said order picking workstation on said order picking platform is adapted for single-stage or multi-stage order picking.

26. The order picking apparatus as claimed in claim 1, wherein said order picking workstation is provided with electronically controlled display elements to assist order picking.

27. The order picking apparatus as claimed in claim 1, including an automated destination control of said movable order picking platform, wherein said order picking platform is adapted to be navigated to a next transfer station after an interchange of load units with said rack.

28. The order picking apparatus as claimed in claim 1, wherein provision and disposal of load units at an appropriate transfer station in said rack is coordinated by a higher-order computer unit.

29. The order picking apparatus as claimed in claim 1, wherein at least one chosen from order picking data, provisioning information and intended direction of travel of said order picking platform is displayed on said order picking workstation.
